(19) United States
(12) Patent Application Publication
(10) Pub. No.: US 2026/0114014 A1
(43) Pub. Date: Apr. 23, 2026

(54) BOTTOM ISOLATION REGION BETWEEN GATE AND BACKSIDE CONTACT

(71) Applicant: International Business Machines Corporation, Armonk, NY (US)

(72) Inventors: Debarghya Sarkar, Latham, NY (US); Ruilong Xie, Niskayuna, NY (US); Kisik Choi, Watervliet, NY (US); Ravikumar Ramachandran, Pleasantville, NY (US); Julien Frougier, Albany, NY (US)

(21) Appl. No.: 18/923,020

(22) Filed: Oct. 22, 2024

(51) Int. Cl. H01L 29/417; H01L 21/283; H01L 27/088; H01L 29/06; H01L 29/423; H01L 29/66; H01L 29/775; H01L 29/786

(52) U.S. Cl. CPC H10D 64/258; H10D 30/6729; H10D 62/116; H10D 64/518; H10D 84/83; H10P 14/40; H10D 30/014; H10D 30/43; H10D 30/6735; H10D 30/6757; H10D 62/121

(57) ABSTRACT

A semiconductor integrated circuit (IC) device is presented that includes a transistor with a gate, a plurality of channels, and a source/drain (S/D) region. A backside contact, that is asymmetric to the S/D region, is in direct contact with a backside of the S/D region. A bottom isolation region is in direct contact with the backside contact and in direct contact with the gate. A bottommost inner spacer is below a bottommost channel of the plurality of channels and in direct contact with the bottom isolation region. The of the bottom isolation region may enable the asymmetry of the backside contact which may lessen routing congestion from the associated backside contact to a backside BEOL network.

### BACKGROUND

The present disclosure relates to fabrication methods and resulting structures for semiconductor devices. More specifically, the present disclosure relates to fabrication methods and resulting semiconductor integrated circuit (IC) devices that include a gate all around (GAA) transistor that includes a bottom isolation region.

Conventional transistors, such as semiconductor IC devices, or the like, incorporate planar field effect transistors (FETs) in which current flows through a semiconducting channel between a source and a drain in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET, generally, is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which a majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for improved control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

### SUMMARY

In an embodiment of the present disclosure, a semiconductor integrated circuit (IC) device is presented. The semiconductor IC device includes a transistor with a gate, a plurality of channels, and a source/drain (S/D) region. The semiconductor IC device includes a backside contact in direct contact with a backside of the S/D region. The backside contact is asymmetric to the S/D region. The semiconductor IC device includes a bottom isolation region in direct contact with the backside contact and in direct contact with the gate. The semiconductor IC device includes a bottommost inner spacer below a bottommost channel of the plurality of channels. The bottommost inner spacer is in direct contact with the bottom isolation region.

In an embodiment of the present disclosure, a semiconductor integrated circuit (IC) device is presented. The semiconductor IC device includes a first region and a second region. The first region includes a first gate, a first plurality of channels, a first source/drain (S/D) region, a first backside contact in direct contact with a backside of the first S/D region, and a first bottom isolation region in direct contact with the first backside contact and in direct contact with the first gate. The second region includes a second gate, a second plurality of channels, a second S/D region, a second backside contact in direct contact with a backside of the second S/D region, and a second bottom isolation region in direct contact with the second backside contact and in direct contact with the second gate. The semiconductor IC device further includes a shared backside interlayer dielectric (ILD) within the first region and within the second region. The first gate directly connects the shared backside ILD, and the second bottom isolation region separates the second gate from the shared backside ILD.

In another embodiment of the present disclosure, a semiconductor integrated circuit (IC) device fabrication method is presented. The method includes forming a first lateral indent within a lower sacrificial layer within a nanolayer stack while retaining a portion of the lower sacrificial layer. The method further includes forming a bottom isolation region within the first lateral indent directly against an upper sacrificial layer that is directly connected to a frontside of the lower sacrificial layer. The method further includes, after forming the bottom isolation region, forming a second lateral indent within the upper sacrificial layer. The method further includes forming a bottom inner spacer within the second lateral indent directly against the bottom isolation region. The method further includes forming a gate directly against the bottom inner spacer and directly against the bottom isolation region. The method further includes forming a backside contact direct against the bottom isolation region, wherein the bottom isolation region is between the backside contact and the gate.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1-FIG. 3 depict cross section views of a semiconductor IC device that includes a bottom isolation region between a gate and a backside contact, according to one or more embodiments of the disclosure.

FIG. 4 depicts a partial structure top-down view of an illustrative semiconductor IC device, according to one or more embodiments of the disclosure.

FIG. 5 through FIG. 20 depict respective cross section fabrication views of a semiconductor IC device that includes or is to include a bottom isolation region between a gate and a backside contact, according to one or more embodiments of the disclosure.

FIG. 21 depicts a flowchart of a method of fabricating a semiconductor IC device that includes a bottom isolation region between a gate and a backside contact, according to one or more embodiments of the disclosure.

### DETAILED DESCRIPTION

The flowcharts and cross-sectional diagrams in the drawings illustrate a method of fabricating semiconductor IC device, such as a processor, filed programmable gate array (FPGA), memory module, or the like. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, for some transistor architectures, integration of the transistors with a backside back end of line (BEOL) network is one of the key challenges to providing increasing packaged IC device densities and performance increases. By incorporating the BEOL network into the semiconductor IC device, there may be a logical and/or functional separation between electrical signal routing and electrical power routing through the semiconductor IC device which may ease routing congestion in some applications.

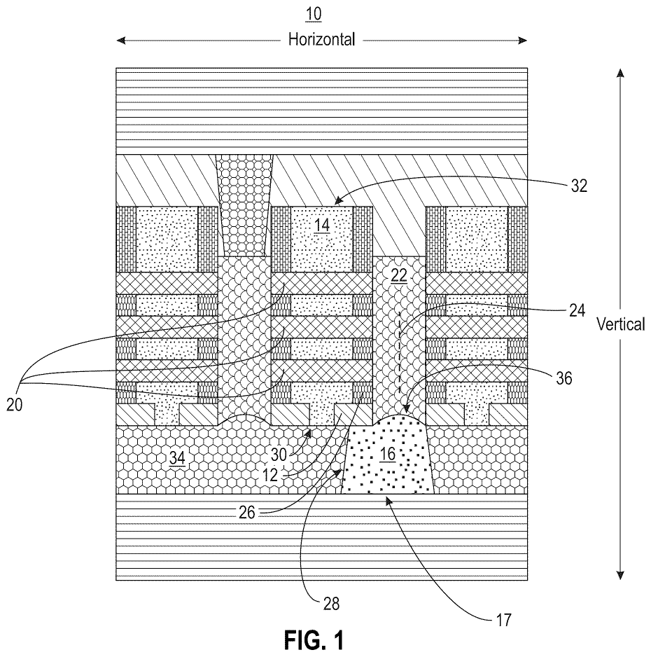

FIG. 1, a semiconductor IC device 10 is presented that includes a bottom isolation region 12 between a gate 14 and a backside contact 16. The semiconductor IC device 10 includes a transistor that includes the gate 14, a plurality of channels 20, and a source/drain (S/D) region 22. The semiconductor IC device 10 further includes the backside contact 16 in direct contact with a backside of the S/D region 22. The backside contact 16 is asymmetric to the S/D region 22. For example, as depicted, the backside contact 16 includes a portion 17 that horizontally extends toward the gate 14 without the corollary portion of the backside contact 16 that would otherwise exist if portion 17 would be mirrored across a vertical bisector 24 of the S/D region 22. The semiconductor IC device 10 further includes the bottom isolation region 12 in direct contact with the backside contact 16 and in direct contact with the gate 14. The semiconductor IC device 10 further includes a bottommost inner spacer 26 that is located below a bottommost channel of the plurality of channels 22. The bottommost inner spacer 26 is in direct contact with the bottom isolation region 12.

In an example, the bottommost inner spacer 26 is further in direct contact with S/D region 22 and in direct contact with the gate 14. In an example, a sidewall 28 of the backside contact 16 is horizontally inset within and below the bottom isolation region 12. In an example, a horizontal dimension of the bottom isolation region 12 is greater than a horizontal dimension of the bottommost inner spacer 26.

In an example, a bottom portion 30 of the gate 14 has a smaller horizontal dimension relative to a top portion 32 of the gate 14. In an example, semiconductor IC device 10 further includes a backside interlayer dielectric (ILD) 34 that is in direct contact with the backside contact 16, is in direct contact with the bottom isolation region 12 and is in direct contact with the gate 14.

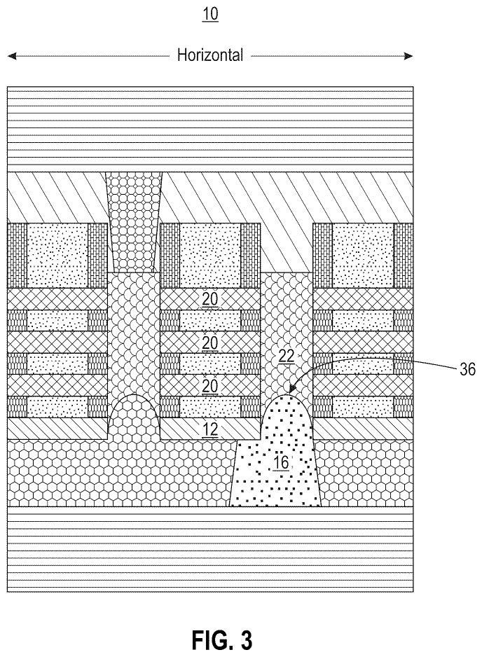

In an example, the bottom isolation region 12 is composed of a first dielectric material and the bottommost inner spacer 26 is composed of a second dielectric material different from the first dielectric material. In an example, an interface 36 between the S/D region 22 and the backside contact 16 is vertically inset within the bottom isolation region 22. In an example, depicted in FIG. 3, the interface 36 between the S/D region 22 and the backside contact 16 is above the bottom isolation region 12. For clarity, FIG. 1 depicts the bottom isolation region 12 as bifurcated or separated beneath the plurality of channels 20 which may be present, for example, in long channel transistors (e.g., the horizontal dimension of the plurality of channels 20 is relatively large) while FIG. 3 depicts a single or continuous bottom isolation region 12 beneath the plurality of channels 20 which may be present, for example, in short channel transistors (e.g., the horizontal dimension of the plurality of channels 20 is relatively small).

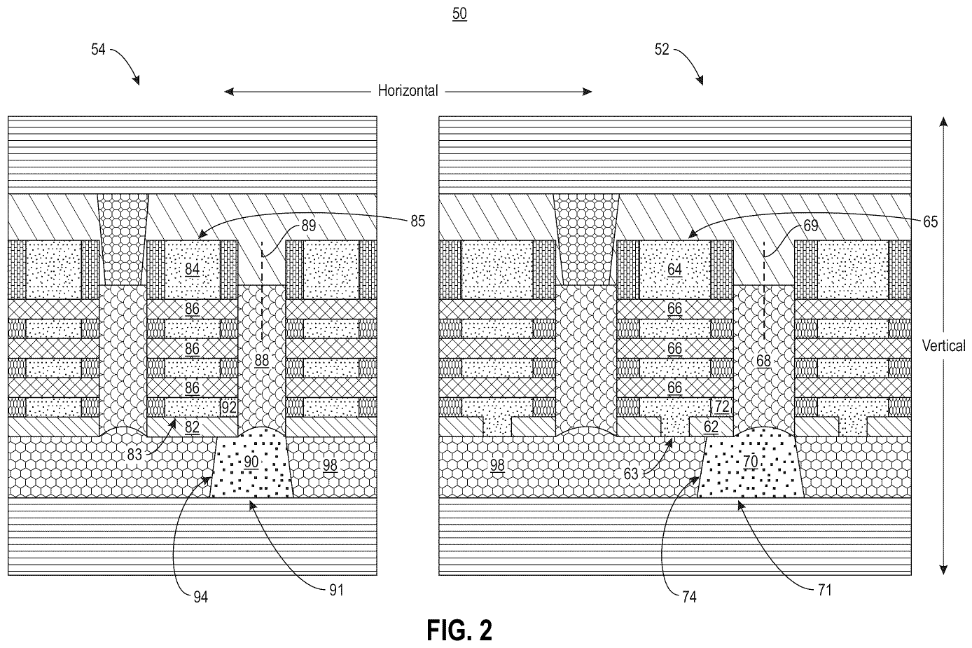

Turing to one or more embodiments of the disclosure and with reference to FIG. 2, a semiconductor IC device 50 is presented that includes a first region 52 and a second region 54 within the same semiconductor IC device 50. The first region 52 may be a long channel device region in which one or more transistors therein have relatively long channels and the second region 54 may be a short channel region in which one or more transistors therein have relatively short channels.

The first region 52 of semiconductor IC device 50 includes a first gate 64, a first plurality of channels 66, a first source/drain (S/D) region 68, a first backside contact 70 in direct contact with a backside of the first S/D region 68, a first bottom isolation region 62 in direct contact with the first backside contact 70 and in direct contact with the first gate 64.

The second region 54 of the semiconductor IC device 50 includes a second gate 84, a second plurality of channels 86, a second S/D region 88, a second backside contact 90 in direct contact with a backside of the second S/D region 88, a second bottom isolation region 82 in direct contact with the second backside contact 90 and in direct contact with the second gate 84.

The semiconductor IC device 50 further includes a shared backside interlayer dielectric (ILD) 98 within the first region 52 and within the second region 54. The first gate 64 is directly connected to the shared backside ILD 98 and the second bottom isolation region 82 separates the second gate 84 from the shared backside ILD 98.

In an example, the first backside contact 70 is asymmetric to the first S/D region 68 and the second backside contact 90 is asymmetric to the second S/D region 88. For example, as depicted, the backside contact 70 includes a portion 71 that horizontally extends toward the first gate 64 without the corollary portion of the backside contact 70 that would otherwise exist if portion 71 would be mirrored across a vertical bisector 69 of the first S/D region 68. Likewise, for example, as depicted, the backside contact 90 includes a portion 91 that horizontally extends toward the second gate 84 without the corollary portion of the backside contact 90 that would otherwise exist if portion 91 would be mirrored across a vertical bisector 89 of the second S/D region 88.

In an example, the first region 52 of the semiconductor IC device 50 further includes a first bottommost inner spacer 72 between the first bottom isolation region 62 and a first bottommost channel of the first plurality of channels 66. In an example, the second region 54 of the semiconductor IC device 50 further includes a second bottommost inner spacer 92 between the second bottom isolation region 82 and a second bottommost channel of the second plurality of channels 86.

In an example, a sidewall 74 of the first backside contact 70 is horizontally inset within and below the first bottom isolation region 62. In an example, a horizontal dimension of the first bottom isolation region 62 is smaller than a horizontal dimension of the second bottom isolation region 82. In an example, a bottom portion 63 of the first gate 64 has a smaller horizontal dimension relative to a top portion 65 of the first gate 64 and wherein a bottom portion 83 of the second gate 84 has a substantially same horizontal dimension relative to a top portion 85 of the second gate 84.

In an example, the first bottom isolation region 62 is composed of a first dielectric material and the first bottommost inner spacer 72 is composed of a second dielectric material different from the first dielectric material. In an example, the shared backside ILD 98 is composed of a third dielectric material different from the first dielectric material and different from the second dielectric material. In an example, a backside of the first gate 64 is below a backside of the second gate 84. In other words, the bottom of the first gate 64 is below the bottom of the second gate 84, as depicted. In an example, respective horizontal dimensions of the first plurality of channels 66 are larger than respective horizontal dimensions of the second plurality of channels 86.

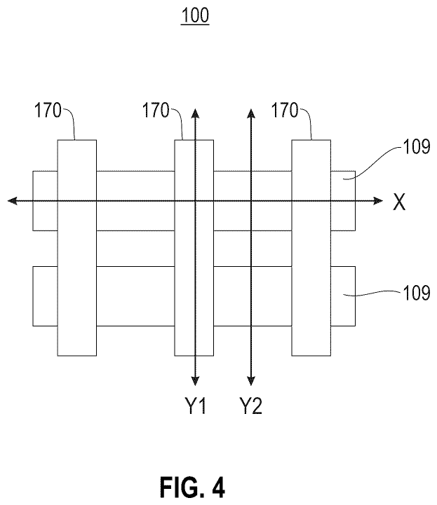

FIG. 4 depicts a partial structure top-down view of an illustrative semiconductor IC device 100, according to one or more embodiments of the disclosure. As currently depicted, semiconductor IC device 100 includes nanolayer rows 109 and replacement gate structures 170. FIG. 4 also depicts cross-sectional planes of the various cross-sectional views of at least some of the drawings. The X cross-sectional plane is through a nanolayer row 109 and across replacement gate structures 170. The Y1 cross-sectional plane is through a replacement gate structure 170 and across nanolayer rows 109. The Y2 cross-sectional plane between replacement gate structures 170 and across nanolayer rows 109.

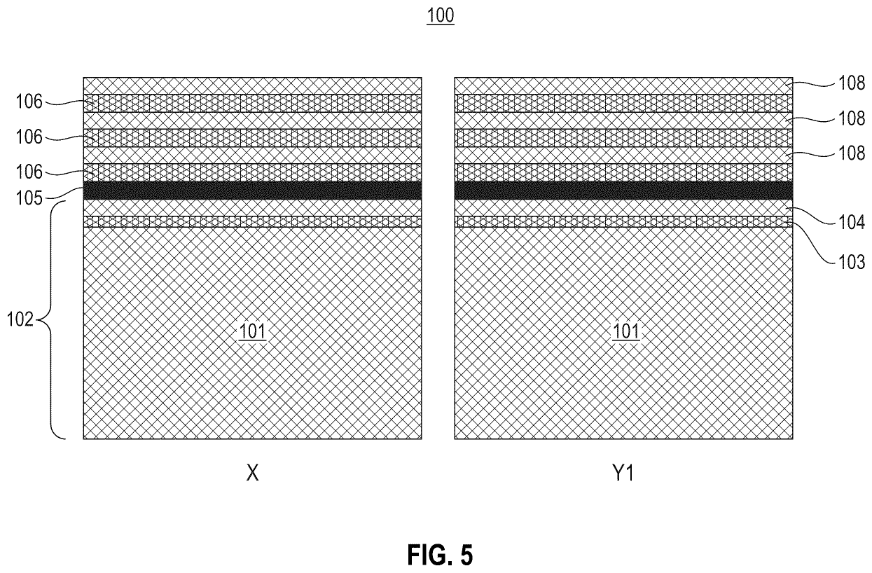

FIG. 5 depicts a cross-sectional view of the semiconductor IC device 100 after initial fabrication operations, in accordance with embodiments of the present disclosure. In these initial fabrication stages, nanolayers are formed upon a substrate structure 102.

The substrate structure 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In another implementation, the substrate structure 102 includes an upper substrate 104, a lower substrate 101, and an insulator layer between the upper substrate and the lower substrate. The upper and lower substrates may be comprised of any other suitable material(s) than those listed above, and the insulator layer may be a dielectric layer, such as an oxide, and may be referred to as a buried oxide (BOX) substrate. In another implementation, as depicted, the substrate structure 102 includes the upper substrate 104, the lower substrate 101, and an etch stop layer 103 between the upper substrate 104 and the lower substrate 101. The etch stop layer 103 may be a dielectric layer and may be any dielectric with etch selectivity to one or both the upper substrate 104 and/or the lower substrate 101.

Nanolayers may be formed upon the substrate structure 102 by forming a lowest sacrificial nanolayer 105 directly on an upper surface of the substrate structure 102. Next, alternating blanket layers of sacrificial nanolayers 106 and active nanolayers 108 may be formed.

In an illustrative example, the lowest sacrificial nanolayer 105 is composed of silicon-germanium (e.g., SiGe, where the Ge ranges from about 50-80%). Further, in an illustrative example, each of the sacrificial nanolayers 106 are composed of silicon-germanium (e.g., SiGe, where the Ge ranges from about 20-30%). In this manner, the lowest sacrificial nanolayer 105 may have adequate etch selectivity to the sacrificial nanolayers 106. Still further, in an illustrative example, the active nanolayers 108 are composed of silicon.

Although it is specifically contemplated that the sacrificial nanolayers 106 and the lowest sacrificial nanolayer 105 can be formed from SiGe and that the active nanolayers 108 can be formed from Si, it should be understood that any appropriate materials can be used instead, as long as the two semiconductor materials have adequate etch selectivity with respect to one another.

In certain embodiments, the sacrificial nanolayers 106, the lowest sacrificial nanolayer 105, and the active nanolayers 108 have a vertical thickness ranging, for example, from approximately 3 nm to approximately 20 nm. Although the range of 3-20 nm is cited as an example range of thickness of the lowest sacrificial nanolayer 105, the sacrificial nanolayers 106 and active nanolayers 108, other thickness of these nanolayers may be used. In certain examples, certain of the lowest sacrificial nanolayer 105, the sacrificial nanolayers 106 and active nanolayers 108 may have different thicknesses relative to one another.

The nanolayers can be deposited by any appropriate mechanism. The alternating blanket nanolayers can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In a particular embodiment, the lowest sacrificial nanolayer 105 may be epitaxially grown from substrate structure 102 and the alternating blanket layers of sacrificial nanolayers 106 and active nanolayers 108 may be epitaxially grown from the lowest sacrificial nanolayer 105. The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

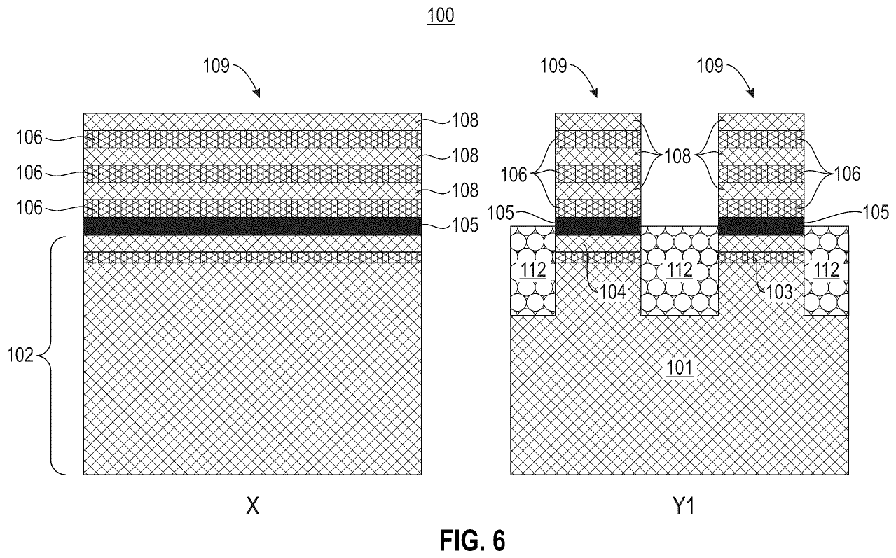

FIG. 6 depicts a cross-sectional view of the semiconductor IC device 100 after fabrication operations, in accordance with embodiments of the present disclosure. In the depicted fabrication stages, the nanolayers may be patterned into nanolayer rows 109 and one or more shallow trench isolation (STI) regions 112 are formed.

To form one or more nanolayer rows 109, a mask layer (not shown) is formed on the uppermost nanolayer. The mask layer may be comprised of any suitable mask or lithography material(s). The mask layer may be patterned and used to perform the nanolayer row 109 patterning process. In the nanolayer row 109 patterning process, any suitable material removal process (e.g., reactive ion etching or RIE) may be used to remove portions of the alternating nanolayers down to the upper substrate 104, down to the etch stop layer 103, or the like. Following the nanolayer row 109 patterning process, one or more nanolayer rows 109 are formed. As depicted, within each nanolayer row 109 there is a lowest sacrificial nanolayer 105 and alternating sacrificial nanolayers 106 and active nanolayers 108 formed from the associated nanolayers, respectively. Subsequently, the mask layer may be removed.

The removal of undesired portion(s) of the nanolayers may further remove undesired portions the substrate structure 102 that are adjacent to respective footprints of nanolayer rows 109 to form STI region openings. The etch may be timed or otherwise controlled to stop the removal of the substrate structure 102 such that the depth or bottom of the one or more STI region openings has a predetermined or desired dimension.

A STI region 112 may be formed within the substrate structure 102 below and adjacent to the nanolayer rows 109 within the STI region openings. For example, one or more STI regions 112 may be formed by depositing isolation material within the STI region openings adjacent to the one or more nanolayer rows 109. A top surface of the one or more STI regions 112 may be at or below a top surface of lowest sacrificial nanolayer 105. The STI region(s) 130 may be formed by depositing STI isolation material, such as a nitride or other suitable dielectric, upon the substrate structure 102. The one or more STI regions 112 may have a volume that sufficiently electrically isolates components or features of neighboring transistors, or the like, and/or may sufficiently electrically isolate neighboring nanolayer rows 109.

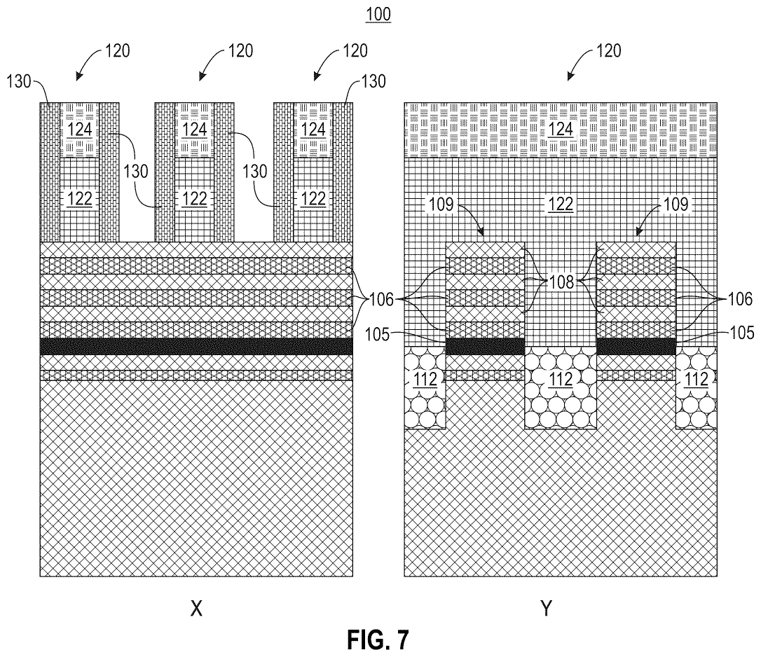

FIG. 7 depicts a cross-sectional view of the semiconductor IC device 100 after fabrication operations, in accordance with embodiments of the present disclosure. In the depicted fabrication stages, one or more sacrificial gate structures 120 and gate spacers 130 may be formed.

The sacrificial gate structures 120 may be formed by initially depositing the sacrificial gate liner layer (e.g., a dielectric, oxide, or the like) upon the one or more STI regions 112 and upon and around the one or more nanolayer rows 109. The sacrificial gate structures 120 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer rows 109. The sacrificial gate structures 120 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 120 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 122, and the sacrificial gate cap 124, respectively, of each of the one or more sacrificial gate structures 120.

The gate spacer(s) 130 may be respectively formed upon the one or more STI regions 112, upon and around the one or more nanolayer rows 109, and upon and around each of the one or more sacrificial gate structures 120. In one example, gate spacers 130 may be formed of a dielectric material(s), such as such as silicon nitride, SiBCN, SiNC, SiN, SiCO, SiNOC, a combination thereof, or the like.

The one or more gate spacers 130 may be formed by a deposition of a blanket gate spacer dielectric material. Excess, undesired, and/or exposed blanket gate spacer dielectric material may be subsequently removed by a substrative removal technique, such as an etch. For example, a directional etch may remove exposed horizontal portion(s) of the blanket gate spacer dielectric material while also leaving vertical portion(s) of the blanket gate spacer dielectric material, upon the sidewall perimeter of each of the one or more sacrificial gate structures 120 intact.

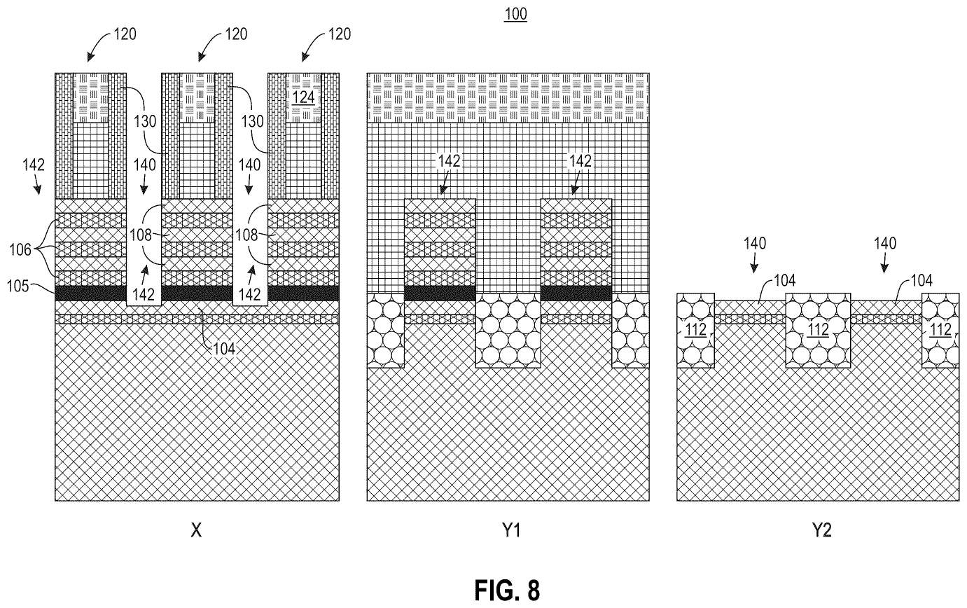

FIG. 8 depicts a cross-sectional view of the semiconductor IC device 100 after fabrication operations, in accordance with embodiments of the present disclosure. In the depicted fabrication stages, source/drain (S/D) canyons 140 may be formed within the one or more nanolayer rows 109 between gate spacers 130 that are associated with neighboring sacrificial gate structures 120. The S/D canyons 140 may separate a single nanolayer row 109 into multiple nanolayer stacks 142, each located underneath a sacrificial gate structure 120.

The one or more S/D canyons 140 may be formed between adjacent sacrificial gate structures 120 by removing respective portions of the sacrificial nanolayers 106 and active nanolayers 108 that are between gate spacers 130 of adjacent or neighboring sacrificial gate structures 120. The one or more S/D canyons 140 may be formed to a depth to stop at or within the upper substrate 104. The nanolayers may be removed by one or more etches that may be selective to the respective material(s) of gate spacers 130, sacrificial gate cap 124, and/or STI regions 112.

The retained one or more portions of one or more nanolayer rows 109 may be such portions of the alternating nanolayers that were protected generally below and/or internal to respective sacrificial gate structures 120 and/or by the associated gate spacers 130. As such, as is depicted, respective sidewalls or end surfaces of the retained sacrificial nanolayers 106, the active nanolayers 108, lowest sacrificial nanolayer 105, may be coplanar with respective outer sidewalls of the associated gate spacers 130.

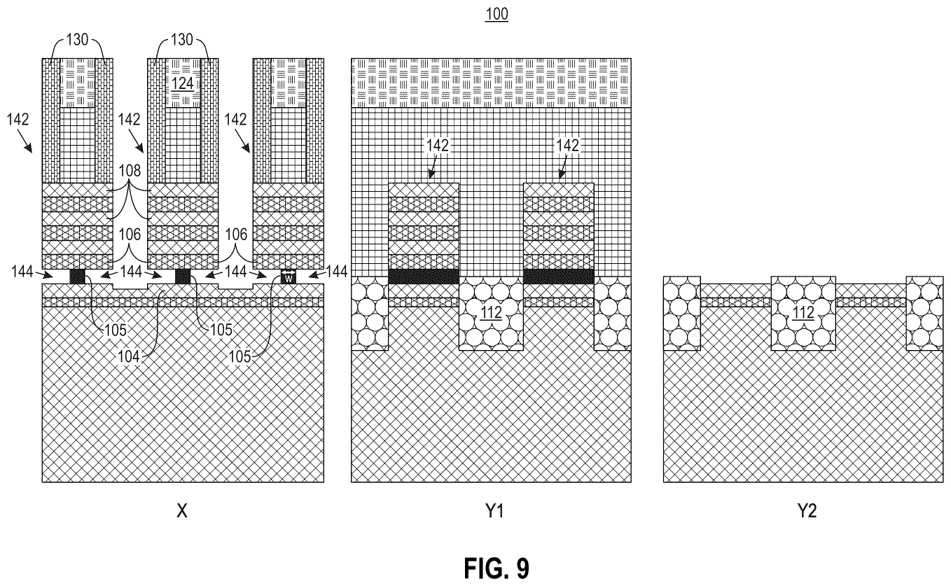

FIG. 9 depicts a cross-sectional view of the semiconductor IC device 100 after fabrication operations, in accordance with embodiments of the present disclosure. In the depicted fabrication stages, indents 144 may be formed by removing respective all or portions of the lowest sacrificial nanolayer 105 within the nanolayer stack(s) 142.

Indents 144 may be formed by a reactive ion etch (RIE) process and/or a wet etch process, which can remove portions of the lowest sacrificial nanolayer 105 with is adequately selective to the active nanolayers 108, the sacrificial nanolayers 106, to the upper substrate 104, to the STI region 112, to the gate spacers 130, to the sacrificial gate cap 124, and/or the like.

The etch consumes all of or a portion of the lowest sacrificial nanolayer 105. For example, in embodiments where the bottom isolation region is to be located under all of the nanolayer stack(s) 142 (depicted for example in FIG. 3), all of the lowest sacrificial nanolayer 105 may be removed (e.g., the horizontal dimension w is zero). In alternative embodiments in which the bottom isolation region is bifurcated under the nanolayer stack(s) 142 (depicted for example in FIG. 1), a portion of the lowest sacrificial nanolayer 105 may be removed (e.g., the horizontal dimension w is non-zero and less than the horizontal dimension of the nanolayer stack 142).

In some implementations, such as those that include one or more long channel transistors, the etch may be timed or otherwise controlled so that only portion of the lowest sacrificial nanolayer 105 may be removed and a portion of the lowest sacrificial nanolayer 105 is retained within the nanolayer stack(s) 142, as depicted. Alternatively, in some implementation, such as those that include one or more short channel transistors, the etch may be timed or otherwise controlled so that substantially all of the sacrificial nanolayer 105 may be removed.

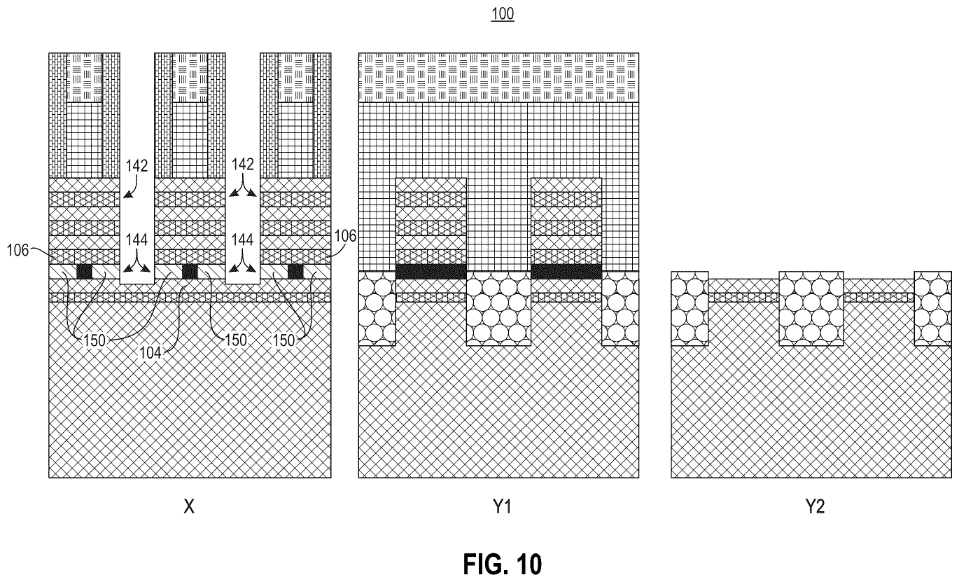

FIG. 10 depicts a cross-sectional view of the semiconductor IC device 100 after fabrication operations, in accordance with embodiments of the present disclosure. In the depicted fabrication stages, a respective bottom isolation region 150 may be formed within a particular indent 144.

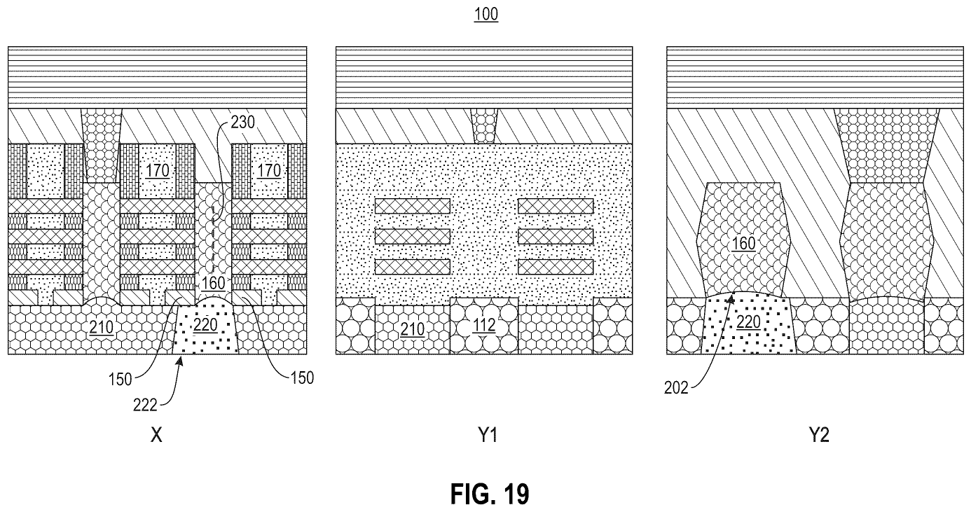

The one or more bottom isolation regions 150 can be formed by ALD or CVD or any other suitable deposition technique that deposits dielectric material within the indents 144. In some examples, the bottom isolation regions 150 are composed of a dielectric that may additionally serve as a good etch stop layer during the formation of an associated backside contact as depicted in FIG. 19, such as SiC, SiOC, AlNₓ, HfO, or the like. In certain implementations, after the formation of the bottom isolation regions 150, an isotropic etch process is performed to create outer vertical surfaces of the bottom isolation regions 150 that align with or are substantially coplanar with the outer vertical surfaces of the associated nanosheet stack 142 there above.

For clarity, and as depicted at the present fabrication stage, bottom isolation regions 150 may be formed directly connected to the bottommost sacrificial layer 106, directly connected to the upper substrate 104, and directly connected to any residual of the bottommost sacrificial nanolayer 105 (if present).

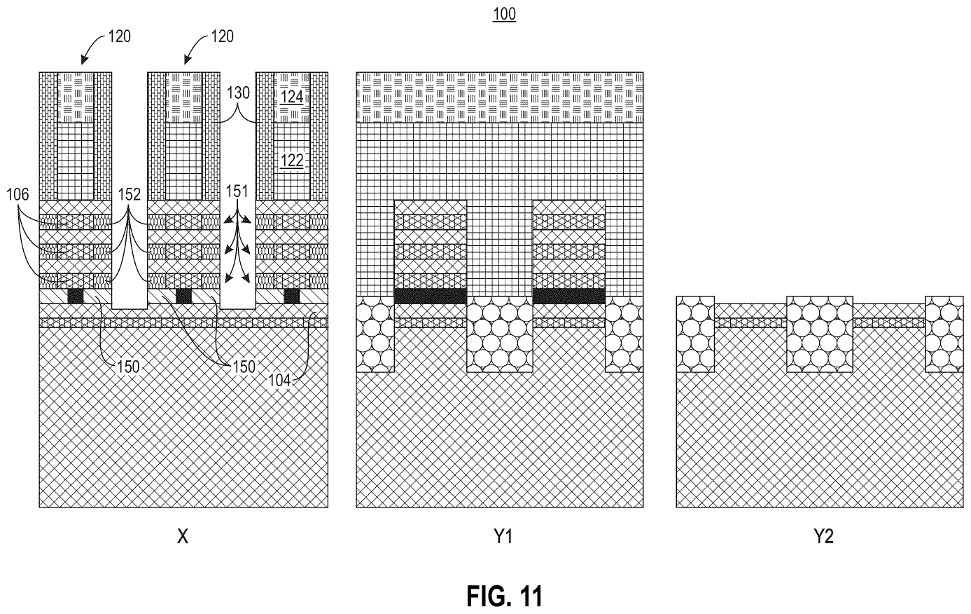

FIG. 11 depicts a cross-sectional view of the semiconductor IC device 100 after fabrication operations, in accordance with embodiments of the present disclosure. In the depicted fabrication stages, the sacrificial nanolayers 106 may be indented and a respective inner spacer 152 may be formed within a particular indent.

Indents 151 may be formed by a reactive ion etch (RIE) process, a wet etch process, or the like which can remove portions of the sacrificial nanolayers 106 not covered by the sacrificial gate 122. The horizontal depth of the indents 151 may be chosen to set a gate length for a replacement gate structure that is formed in place of one sacrificial gate structure 120. When the sacrificial nanolayers 106 are composed of SiGe and when active nanolayers 108 are Si, the directional RIE can use a boron-based chemistry or a chlorine-based chemistry, for example, which recesses or removes the exposed end portions of sacrificial nanolayers 106 (e.g., end portions of sacrificial nanolayers generally below gate spacer 130).

The one or more inner spacers 152 can be formed by ALD or CVD or any other suitable deposition technique that deposits a dielectric material within the indent(s), thereby forming the inner spacers 152. In some examples, the inner spacers 152 are composed of a low-K dielectric material (a material with a lower dielectric constant relative to SiO₂), SiN, SiO, SiBCN, SiOCN, SiCO, etc. or any other suitable dielectric material. In some embodiments, as depicted, the dielectric material of the inner spacers 152 is different than the material of the bottom isolation region 150. For example, the material of the inner spacers 152 to achieve electrical isolation between a S/D regio and the replacement gate structure while the material of the bottom isolation region 150 may be chosen to provide robust etch selectivity associated with the formation of backside contacts.

In certain implementations, after the formation of the inner spacers 152, a directional etch process is performed to create substantially vertical sidewalls of the inner spacers 152 that may be substantially coplanar with the vertical sidewalls of the active nanolayers 108 and/or of the gate spacers 130.

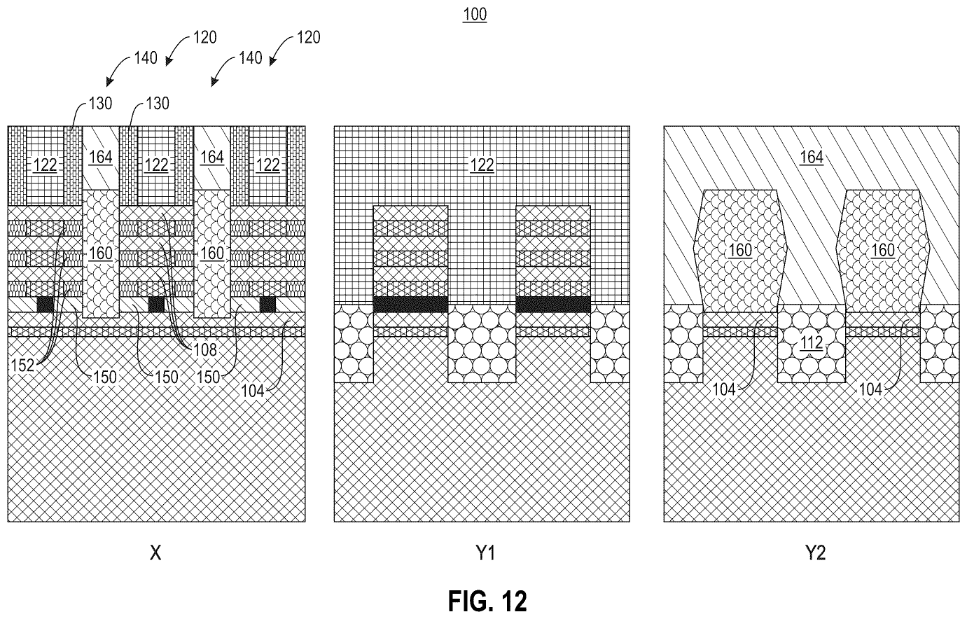

FIG. 12 depicts a cross-sectional view of the semiconductor IC device 100 after fabrication operations, in accordance with embodiments of the present disclosure. In the depicted fabrication stages, one or more source/drain (S/D) regions 160 may be formed upon upper substrate 104 within S/D canyons 140.

Each S/D region 160 forms either a source or a drain, respectively, of respective one or more GAA FETs and may be connected to respective end surfaces of active nanolayers 108 thereof. Each of the S/D region 160 may be composed of a semiconductor material and a dopant. As used herein, a “source/drain” region can be a source region or a drain region depending on subsequent wiring and application of voltages during operation of the transistor. The semiconductor material that provides each of the S/D region 160 is composed of one of the semiconductor materials mentioned above for the semiconductor structure 102. The semiconductor material that provides the S/D region 160 can be compositionally the same, or compositionally different from each active nanolayers 108. The semiconductor material that provides each active nanolayers 108 is however compositionally different from each sacrificial nanolayer 106. The dopant that is present in the S/D region 160 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous.

The S/D region(s) 160 may be formed by epitaxially growth within the S/D canyons 140. In some examples, S/D region(s) 160 are formed by in-situ doped epitaxial growth. In some embodiments, the S/D region(s) 160 epitaxial growth may overgrow above the upper surface of the semiconductor IC device 100. In some implementation, all n-type S/D regions 160 may be formed and subsequently all p-type S/D regions 160 may be formed, or vice versa.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si:C for n-type transistors.

In certain implementations, the S/D region(s) 160 may be overgrown and then partially recessed such that an upper portion of the S/D region(s) 160 are removed. For example, the upper portion of the one or more S/D region(s) 160 may be etched or otherwise removed. The etch may be timed or otherwise controlled to stop the removal of S/D region(s) 160 such that the top surface of S/D region(s) 160 is above the upper surface of the topmost active nanolayer 108 so as to appropriately contact the end surface of the topmost active nanolayer 108.

For clarity, because of the utilization and structure of the bottom isolation region(s) 150, a backside contact placeholder need not be formed within the within S/D canyons 140 prior to the S/D region(s) 160 being formed. In other words, because of the utilization and structure of the bottom isolation region(s) 150, the semiconductor IC device 100 may not include backside contact placeholders underneath the S/D regions 160.

Further, as shown in FIG. 12, in the depicted fabrication stages, interlayer dielectric (ILD) 164 is formed upon the one or more source/drain (S/D) regions 160 and upon at least the sidewalls of the sacrificial gate structures 120 and may be further formed upon the STI region(s) 112.

The ILD 164 may be formed by depositing a dielectric material. The ILD 164 can be any suitable material, such as, for example, porous silicates, carbon doped oxides, silicon dioxides, silicon nitrides, silicon oxynitrides, or other dielectric materials. Any manner of forming the ILD 164 can be utilized. The ILD 164 can be formed using, for example, CVD, PECVD, ALD, flowable CVD, spin-on dielectrics, or PVD.

In an example, the ILD 164 may be formed to a thickness above the top surface of the sacrificial gate structures 120. Subsequently, a planarization process, such as a CMP, may be performed to remove the sacrificial gate cap 124 (therefore not depicted in FIG. 12), to partially remove the excess ILD 164, and to partially remove the gate spacers 130. The planarization may also partially remove some of the sacrificial gate 122 or may at least expose the sacrificial gate 122 of the sacrificial gate structures 120. The CMP may create a planar or horizontal top surface for the semiconductor IC device 100. In other words, the respective top surfaces of ILD 164, gate spacers 130, sacrificial gates 122 may be coplanar.

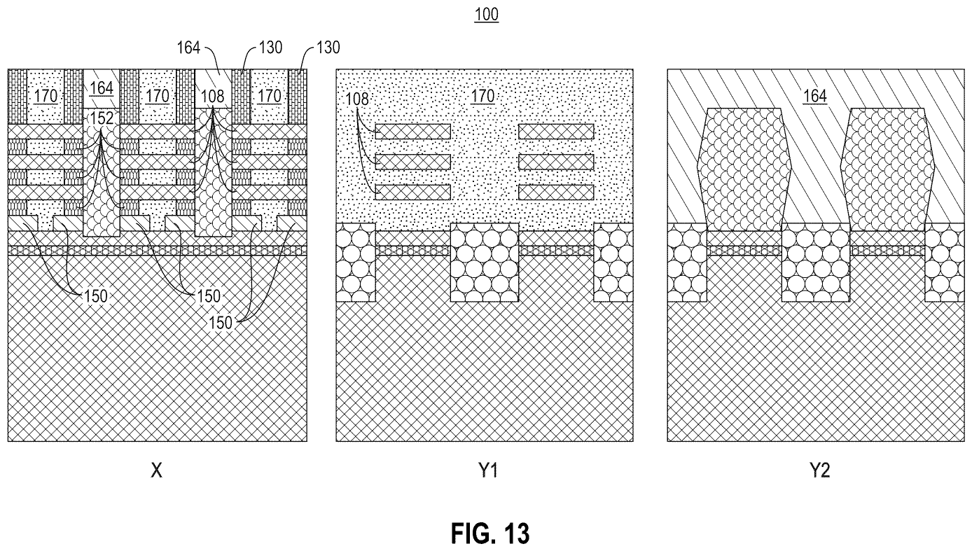

FIG. 13 depicts a cross-sectional view of the semiconductor IC device 100 after fabrication operations, in accordance with embodiments of the present disclosure. In the depicted fabrication stages, the sacrificial gate structures 120 are removed, the active nanolayers 108 may be released, and replacement gate structures 170 may be formed in place of the removed sacrificial gate structures 120.

The sacrificial gate structure 120 may be removed by initially removing the sacrificial gate 122 and sacrificial gate oxide by a removal technique, such as one or more series of etches. For example, such removal may be accomplished by an etching process which may include a dry etching process such as RIE, plasma etching, ion etching or laser ablation. The etching can further include a wet chemical etching process in which one or more chemical etchants are used to remove the sacrificial gate 122 and sacrificial gate oxide of the sacrificial gate structures 120. Appropriate etchants may be used that remove the sacrificial gate 122 and/or sacrificial gate oxide selective to the active nanolayers 108, gate spacers 130, inner spacers 152, or the like.

The active nanolayers 108 may be released by removing the sacrificial nanolayers 106. The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, inner spacers 152, gate spacers 130, or the like. After the removal of sacrificial nanolayers 106, void spaces may exist between the active nanolayers 108.

For clarity, the removal of at least the sacrificial gate 122 and the sacrificial nanolayers 106 generally form a replacement gate structure opening. A particular replacement gate structure 170 may be formed around the active nanolayers 108 within one replacement gate structure opening.

Replacement gate structure(s) 170 may be formed by initially forming an interfacial layer (not shown) on the interior surfaces of the gate structure opening (e.g., interior surfaces of gate spacer 130, the interior surfaces of the active nanolayers 108, interior surfaces of inner spacers 152, and upon the bottom isolation region(s) 150. Then, a high-K layer may be formed to cover the surfaces of exposed surfaces of the interfacial layer. The high-K layer can be deposited by any suitable techniques, such as ALD, CVD, metal-organic CVD (MOCVD), physical vapor deposition (PVD), thermal oxidation, combinations thereof, or other suitable techniques. A high-K dielectric material is a material with a higher dielectric constant than that of SiO₂, and can include e.g., LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The high-κ layer can include a single layer or multiple layers, such as metal layer, liner layer, wetting layer, and adhesion layer.

Replacement gate structure(s) 170 may be further formed by depositing a work function metal (WFM) gate upon the high-κ layer. The WFM gate can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the WFM gate can be reduced by chemical-mechanical polishing (CMP) and/or etching. Therefore, the planarization process can be provided by CMP. Other planarization process can include grinding and polishing. In general, the work function metal (WFM) gate sets the threshold voltage (Vt) of the device. The high-K layer separates the WFM gate from the nanolayer channel (i.e., active nanolayers 108). Other metals that may be desired to further fine tune the effective work function (eWF) and/or to achieve a desired resistance value associated with current flow through the gate in the direction parallel to the plane of the nanolayer channel.

The one or more replacement gate structures 170 may be further formed by depositing a conductive fill gate upon the WFM gate. The conductive fill gate can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 170 formation, the top surface of the semiconductor IC device 100 may be planarized by a planarization technique such as a CMP, mechanical grinding process, or the like. After the planarization technique, respective top surfaces of the ILD 164, gate spacers 130, replacement gate structure(s) 170, may be horizontal and/or may be at least substantially coplanar.

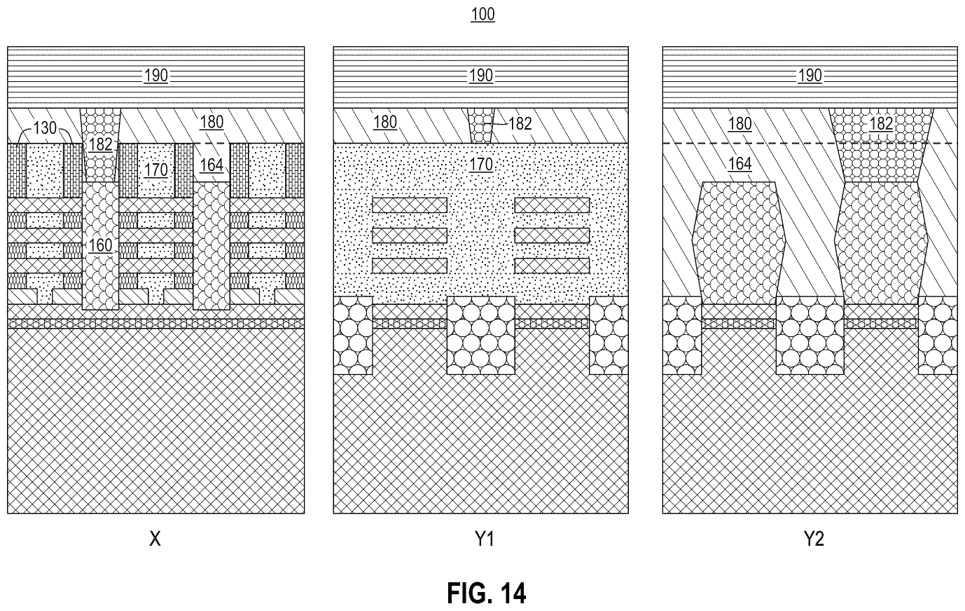

FIG. 14 depicts cross-sectional views of the semiconductor IC device 100 after fabrication operations, in accordance with embodiments of the present disclosure. In the depicted fabrication stages, frontside ILD 180 may be formed, one or more frontside contacts 182 may be formed, a frontside back end of the line (BEOL) network 190 may be formed, and a carrier wafer (not shown) may be bonded thereto.

The frontside contact frontside ILD 180 may be formed upon respective top surfaces of replacement gate structure(s) 170, ILD 164, and gate spacers 130. The frontside contact frontside ILD 180 may be formed by depositing a dielectric material, such as, for example, porous silicates, carbon doped oxides, silicon dioxides, silicon nitrides, silicon oxynitrides, or other dielectric materials. The material of the frontside contact frontside ILD 180 may be the same as the material of the ILD 164, as depicted. Alternatively, the frontside contact frontside ILD 180 may be a relatively different dielectric material than the dielectric material of ILD 164.

The frontside contacts 182 may be formed by patterning respective frontside contact openings within the frontside ILD 180, the frontside contact frontside ILD 180, respectively, from the frontside (i.e., from above the semiconductor IC device 100, as depicted, downward to respective structures thereof). The frontside contacts 182 may be in direct or indirect physical and electrical contact with respective material(s) of one or more regions of the semiconductor IC device 100.

The frontside contacts 182 may be formed by depositing conductive material such as metal into the respective frontside contact opening(s). In an example, frontside contacts 182 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. In embodiments, the frontside contacts 182 are fabricated in middle-of-line (MOL) fabrication operations and may be illustrations of MOL contacts.

Further in the depicted fabrication stages, a frontside back end of line (BEOL) network 190 may be formed and a carrier wafer (not shown) may be bonded to the frontside BEOL network 190. In the semiconductor IC device fabrication industry, there are three sections referred to in a build: front-end-of-line (FEOL), BEOL, and the section that connects those two together, the MOL. The FEOL is made up of devices, e.g., transistors, the BEOL is made up of interconnects and wiring, and the MOL includes interconnects between the FEOL and BEOL and material to prevent the diffusion of BEOL conductive material(s) to the FEOL devices.

The BEOL section is the portion of IC fabrication where the individual devices (e.g., transistors, capacitors, resistors, etc.) become interconnected with wiring on the semiconductor IC device, e.g., the metallization layer or layers of a wafer. The BEOL section includes contacts, insulating layers (dielectrics), metal levels, and bonding sites for chip-to-package connections. In the BEOL section, part of the fabrication stage contacts (pads), interconnect wires, vias and dielectric structures are formed. For modern IC processes, more than one metal layers may be added in the BEOL section.

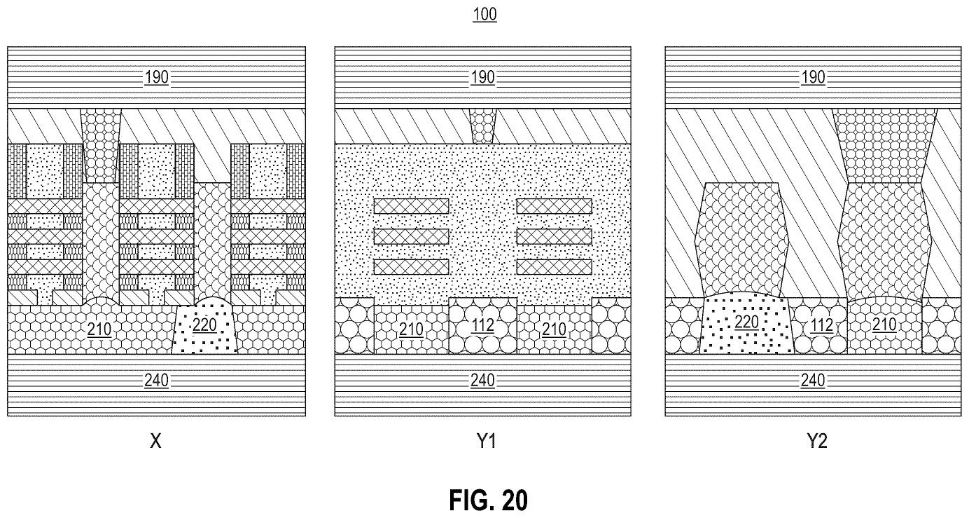

In the present example, there are multiple BEOL levels each on opposites sides of the semiconductor IC device 100. First, a frontside BEOL network 190 is formed on the frontside of the semiconductor device 100. Subsequently, a backside BEOL network 240, as depicted in FIG. 20, may be formed.

In the depicted example, the frontside BEOL network 190 is formed over the frontside contact frontside ILD 180 and upon the frontside contacts 182. Respective wires within the frontside BEOL network 190 may be electrically connected to the one or more S/D regions 160, to the one or more replacement gate structure(s) 170, or the like, by a respective frontside contacts 182. For example, respective wire(s) within the frontside BEOL network 190 may be electrically connected to an appropriate S/D region 160 by a frontside contact 182 and another and different group of respective wire(s) within the frontside BEOL network 190 may be electrically connected to an appropriate replacement gate structure 170 by a different frontside contact 182, etc.

The frontside BEOL network 190 can include one or more interconnect dielectric material layers (including one of the dielectric materials mentioned above for the frontside ILD 180) and contains conductive wires (the conductive wires can be composed of any electrically conductive material, metal, electrically conductive metal alloy, or the like) embedded therein. In some embodiments, the frontside conductive wires within the frontside BEOL network 190 are composed of Cu. The frontside BEOL network 190 can include “x” numbers of frontside metal levels, wherein “x” is an integer starting from 1. The frontside BEOL network 190 may further contain conductive pads that are connected to one or more of the conductive wires and may be used to connect the semiconductor IC device 100 to an external and/or higher-level structure, such as a chip carrier, motherboard, or the like.

The illustrated semiconductor IC device 100 may be further fabricated by bonding carrier wafer to the frontside BEOL network 190. The carrier wafer can include one of the semiconductor materials mentioned above for the semiconductor structure and the carrier wafer may be attached to the semiconductor IC device 100 by a wafer-to-wafer bonding technique.

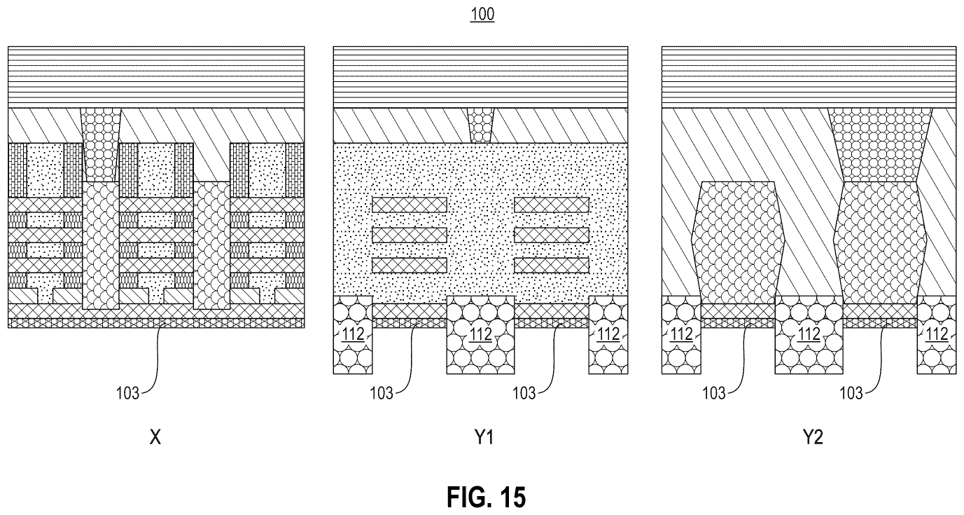

FIG. 15 depicts cross-sectional views of the semiconductor IC device 100 after fabrication operations, in accordance with embodiments of the present disclosure. In the depicted fabrication stages, bottom substrate 101 may be removed. The bottom substrate 101 may be removed may be recessed by flipping the semiconductor IC device 100 and removing bottom substrate 101 by appropriate substrative removal techniques, such as one or more series of etches. The one or more etches may be timed or otherwise controlled to remove the material of bottom substrate 101 selective to the STI regions 112 and may utilize the etch stop layer 103 as an etch stop.

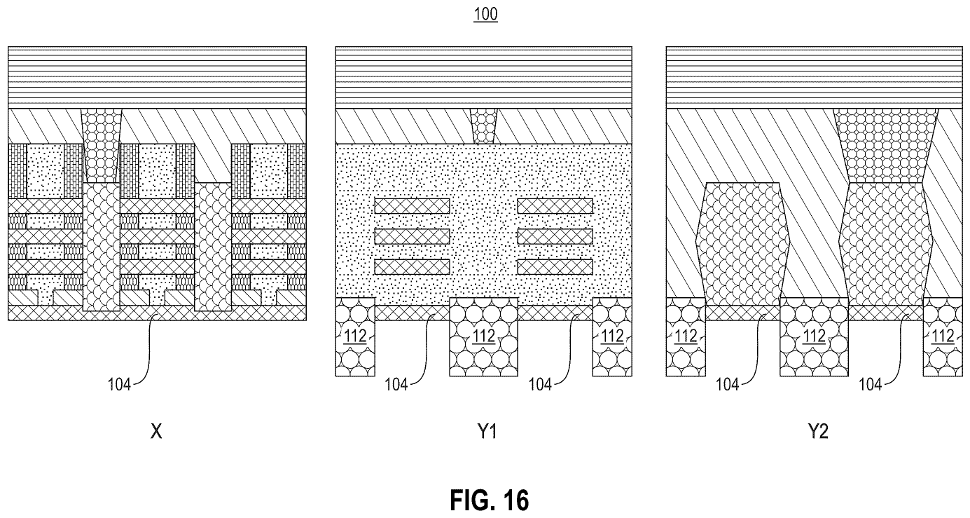

FIG. 16 depicts cross-sectional views of the semiconductor IC device 100 after fabrication operations, in accordance with embodiments of the present disclosure. In the depicted fabrication stages, etch stop layer 103 may be removed. The etch stop layer 103 may be removed by appropriate substrative removal techniques, such as one or more series of etches. The one or more etches may be timed or otherwise controlled to remove the material etch stop layer 103 selective to the STI regions 112 and may utilize the upper substrate 104 as an etch stop.

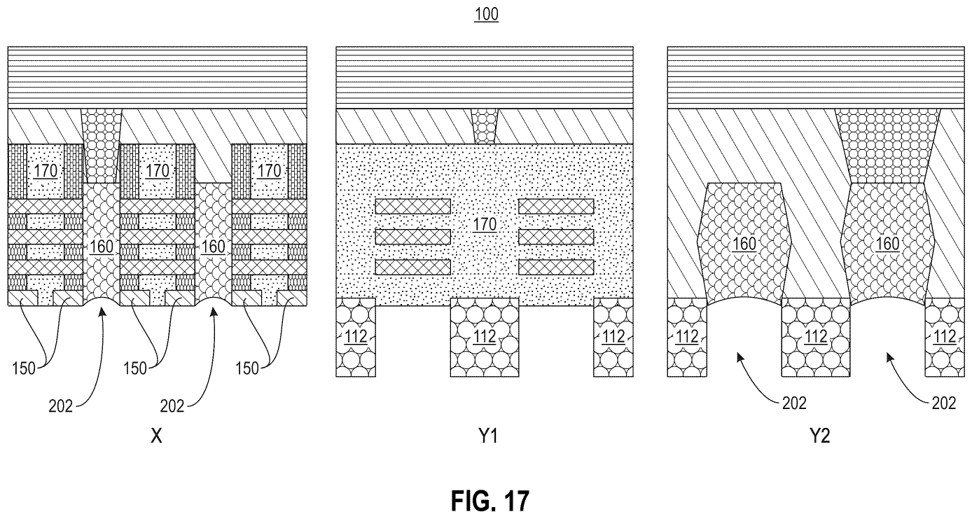

FIG. 17 depicts cross-sectional views of the semiconductor IC device 100 after fabrication operations, in accordance with embodiments of the present disclosure. In the depicted fabrication stages, upper substrate 104 may be removed. The upper substrate 104 may be removed by appropriate substrative removal techniques, such as one or more series of etches. The one or more etches may be timed or otherwise controlled to remove the material upper substrate 104 selective to the STI regions 112, the replacement gate structures 170, and the bottom isolation regions 150.

In the present fabrication stage, the bottom isolation regions 150 may serve as an etch stop and may provide robust etch selectivity relative to upper substrate 104, so as to adequately protect or mask the above regions of the semiconductor IC device 100. The etch that removes the upper substrate 104 may further partially etch or gouge those S/D regions 160 that do not have adequate etch selectivity with respect thereto. For example, when the upper substrate 104 is composed of Si, the etch to remove the upper substrate 104 may further partially etch or gouge those S/D regions 160 that are also composed of Si. The partial etch or gouging of these S/D regions 160 may form a gouge 202 within the S/D regions 160. As this gouge 202 is formed from the backside of the semiconductor IC device, such gouge 202 may have generally a larger perimeter near the bottom of the gouge 202 tapering to having a smaller perimeter near the top of the gouge 202, as depicted.

For clarity, the vertical thickness of the upper substrate 104 may be chosen such that the upper substrate 104 may be fully removed, in the present fabrication stage by a etch that does not adversely damage the S/D region(s) 160. For example, because the vertical thickness of the upper substrate 104 is adequately thin, the over etching of the etchant that removes the upper substrate 104 may be adequately controlled so that a relatively small gouge 202 is present at the bottom of the S/D region 160 or so that a controlled and relatively larger gouge is present at the bottom of the S/D region (e.g., as would be associated with embodiments similar to FIG. 3).

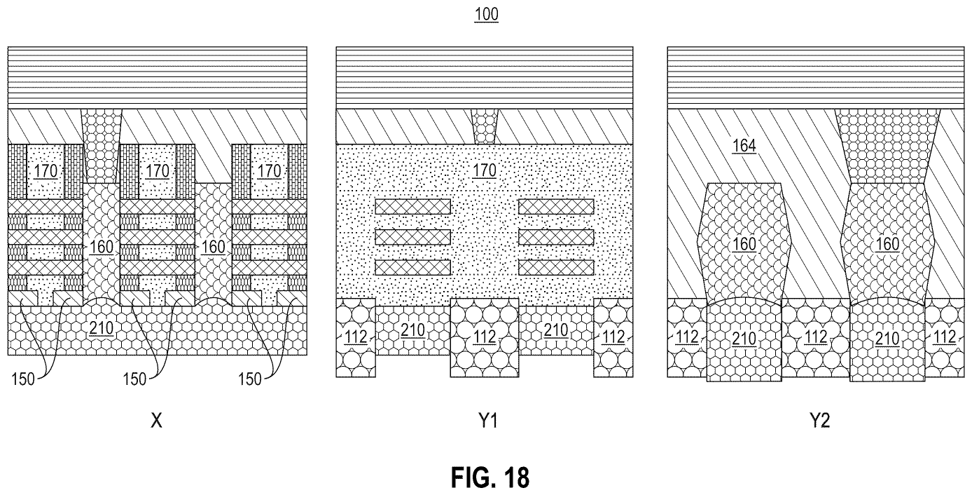

FIG. 18 depicts cross-sectional views of the semiconductor IC device 100 after fabrication operations, in accordance with embodiments of the present disclosure. In the depicted fabrication stages, a backside ILD 210 may be formed.

The backside ILD 210 may be formed upon the backside of the semiconductor IC device 100 (i.e., as depicted from below the semiconductor IC device 100 upward). The backside ILD 210 may be formed directly upon the backside bottom isolation region(s) 150, upon the backside of the replacement gate structures 170 (if applicable), upon the STI regions 112, and upon the backside of the S/D regions 160. The backside ILD 210 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 210 can be utilized. The backside ILD 210 can be formed using, for example, CVD, PECVD, ALD, flowable CVD, spin-on dielectrics, or PVD.

In an example, as depicted, the material of the backside ILD 210 may be the same material as the ILD 164. In alternative examples, the material of the backside ILD 210 may be chosen to achieve a predetermined electrical isolation metric that the dielectric material of ILD 164 could not achieve, if utilized. For example, ILD 164 may be silicon dioxide and the backside ILD 210 may be a low-K dielectric material.

Subsequently, a planarization process, such as a CMP, may planarize the bottom surface of the backside ILD 210 and a bottom surface of the STI regions 112. As a result, the respective bottom surfaces of the STI regions 112 and backside ILD 210 may be substantially horizontal and/or substantially coplanar.

FIG. 19 depicts cross-sectional views of the semiconductor IC device 100 after fabrication operations, in accordance with embodiments of the present disclosure. In the depicted fabrication stages, one or more backside contacts 220 may be formed.

The one or more backside contacts 220 may be formed by initially forming associated backside contact openings by lithography and etch process(es). In such process(es), a mask (not shown) may be applied to the backside of the semiconductor IC device 100 and patterned. Openings in the patterned mask may sequentially expose the portion(s) of the underlying backside ILD 210 that are to be removed while other protected portions of semiconductor IC device 100 may be protected and retained.

A backside contact opening may be asymmetrically located with respect to an associated S/D region 160. For example, the backside contact opening may extend more toward one particular adjacent replacement gate structure 170 relative to the other adjacent replacement gate structure 170 from a vertical bisector 230 of the S/D region 160. This shape of the backside contact opening may result in a portion 222 of the backside contact 220 that is relatively closer to one particular adjacent replacement gate structure 170 relative to the dimension from the backside contact 220 to the other adjacent replacement gate structure 170. Because of the utilization of the bottom isolation region 150, the formation of the backside contact opening with this structural shape may result in the shape of backside contact 220 that includes portion 222 that may lessen routing congestion from the associated backside contact 220 to the backside BEOL network.

A backside contact opening may be formed to expose the associated S.D region 160 there above by removing the associated portion of the backside ILD 210. Such removal may remove the backside ILD 210 material with etch selectivity to the STI regions 112, to the bottom isolation regions 150, to the replacement gate structures 170 (if applicable).

The backside contacts 220 may be further formed by forming a particular backside contact 220 within a respective backside contact opening against the associated S/D region 160. The backside contacts 220 may be formed by depositing conductive material, such as metal, within the backside contact openings. In an example, multiple backside contacts 220 may be simultaneously formed by depositing a liner, such as Ni, NiPt or Ti, etc. onto the backside of semiconductor IC device 100 and into the backside contact openings, depositing an adhesion liner, such as TiN, TaN, etc. upon the liner, and by depositing a conductive fill, such as Al, Ru, W, Co, Cu, etc. upon the adhesion liner.

For clarity, because backside contact 220 may be formed within the backside contact opening against S/D region 160, the backside contact 220 may be generally formed within the gouge 202 of the applicable one or more S/D regions 160. Subsequently, a planarization process, such as a CMP, may expose a bottom surface of the backside ILD 210, the respective bottom surfaces of the backside contacts 220, and the respective bottom surface of the STI regions 112. As a result, the respective bottom surfaces of backside contacts 220, the STI regions 112, and the backside ILD 210 may be substantially horizontal and/or substantially coplanar.

FIG. 20 depicts cross-sectional views of the semiconductor IC device 100 after fabrication operations, in accordance with embodiments of the present disclosure. In the depicted fabrication stages, a backside BEOL network 240 may be formed.

The backside BEOL network 240, such as a backside power distribution network (BSPDN) may be formed upon the backside contacts 220, upon the backside ILD 210, upon the STI regions 112, etc. The backside BEOL network 240 may include signal wires for signal routing and power wires for providing power potential (e.g., VDD, VSS, etc.). The backside BEOL network 240 may allow for the distribution of power wires and signal wires between both the frontside and backside of the semiconductor IC device. The backside BEOL network 240 may further allow for the full or partial decoupling of signal routing and/or power routing and/or allows for dividing or splitting power wires and/or signal wires between both the frontside BEOL network 190 and the backside BEOL network 240 of the semiconductor IC device 100. By also incorporating the backside BEOL network 240, wire and contact routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 240 may be electrically connected to the one or more S/D regions 160 by way of a particular backside contact 220. For example, a first backside wire within the backside BEOL network 240 may be electrically connected to one or more different backside contacts 220, or the like.

The backside BEOL network 240 can include one or more interconnect dielectric material layers and contains backside conductive wires and/or interconnects, such as VIAs, embedded therein. In some embodiments, the backside wires within the backside BEOL network 240 are composed of Cu. The backside BEOL network 240 can include “x” numbers of backside metal levels, wherein “x” is an integer starting from 1. If not included in frontside BEOL network 190, backside BEOL network 240 may further contain conductive pads that are connected to one or more of the backside metal wires and may be used to connect the semiconductor IC device 100 to the external and/or higher-level structure.

In an example, signal routing and power routing is effectively split between the frontside BEOL network 190 and the backside BEOL network 240. For example, at least 90% of the frontside metal wires (e.g., furthest from the depicted transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires. Power routing wires may be less dense than signal routing wires. A signal routing wire is defined herein as a conductive feature, such as a wire, interconnect, or the like, that is configured to carry or have a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

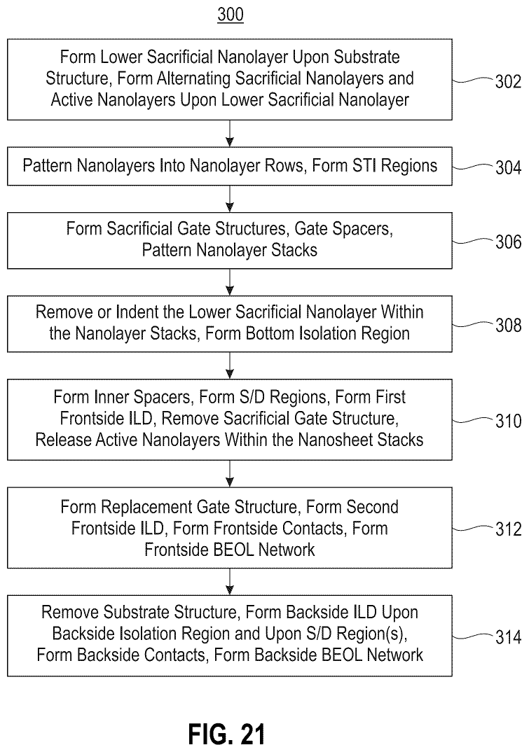

FIG. 21 depicts a flow diagram illustrating method 300 to fabricate a semiconductor IC device, such as semiconductor IC device 100. The depicted fabrication operations of method 300 are illustrated and described above with reference to one or more of FIG. 5 through FIG. 20 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming the bottommost sacrificial nanolayer 105 upon the substrate structure 102 and with forming the alternating sacrificial nanolayers 106 and active nanolayers 108 upon the bottommost sacrificial nanolayer 105.

At block 304, method 300 may continue with pattern the nanolayers into nanolayer rows 109 and with forming STI regions 112 between the nanolayer rows 109. At block 306, method may continue with forming sacrificial gate structures 120, with forming gate spacers 130, and with patterning the nanolayer rows 109 into nanolayer stacks 142.

At block 308, method 300 may continue with removing completely, or indenting, the lowest sacrificial layer 105 within the nanolayer stacks 142 and with forming the bottom isolation region 150 within the associated void formed by the partial or full removal of the lowest sacrificial layer 105.

At block 310, method 300 may continue with forming inner spacers 152, with forming S/D regions 160, with forming ILD 164, with removing sacrificial gate structures 120, and with releasing the active nanolayers 108 within the nanosheet stacks 142 by removing the sacrificial nanolayers 106.

At block 312, method 300 may continue with forming the respective replacement gate structure 170 within the opening formed by the removal of the sacrificial gate structure 120 and the releasing of the active nanolayers 108. At block 312, method 300 may further continue with forming ILD 180, with forming frontside contacts 182, and with forming frontside BEOL network 190.

At block 314 method 300 may continue with removing the substrate structure 102, with forming backside ILD 210, with forming backside contacts 220, and with forming backside BEOL network 240.

In a particular embodiment, method 300 includes forming a first lateral indent 144 within a lower sacrificial layer (e.g., lowest sacrificial layer 105) within a nanolayer stack 142 while retaining a portion of the lower sacrificial layer. In this embodiment, method 300 may further include forming the bottom isolation region 150 within the first lateral indent 144 directly against an upper sacrificial layer (e.g., bottommost sacrificial layer 106) that is directly connected to a frontside of the lower sacrificial layer. In this embodiment, method 300 may further include, after forming the bottom isolation region, forming a second lateral indent 151 within the upper sacrificial layer and with forming a bottom inner spacer 152 within the second lateral indent directly against the bottom isolation region 150. In this embodiment, method 300 may further include forming a gate (e.g., replacement gate structure 170) directly against the bottom inner spacer 152 and directly against the bottom isolation region 150 and with forming the backside contact 220 direct against the bottom isolation region 150 such that the bottom isolation region 150 is between the backside contact 220 and the gate.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a transistor comprising a gate, a plurality of channels, and a source/drain (S/D) region;
a backside contact in direct contact with a backside of the S/D region, wherein the backside contact is asymmetric to the S/D region;
a bottom isolation region in direct contact with the backside contact and in direct contact with the gate; and
a bottommost inner spacer below a bottommost channel of the plurality of channels, wherein the bottommost inner spacer is in direct contact with the bottom isolation region.

2. The semiconductor IC device of claim 1, wherein the bottommost inner spacer is further in direct contact with S/D region and in direct contact with the gate.

3. The semiconductor IC device of claim 1, wherein a sidewall of the backside contact is horizontally inset within and below the bottom isolation region.

4. The semiconductor IC device of claim 1, wherein a horizontal dimension of the bottom isolation region is greater than a horizontal dimension of the bottommost inner spacer.

5. The semiconductor IC device of claim 1, wherein a bottom portion of the gate has a smaller horizontal dimension relative to a top portion of the gate.

6. The semiconductor IC device of claim 1, further comprising:
a backside interlayer dielectric (ILD) that is in direct contact with the backside contact, is in direct contact with the bottom isolation region, and is in direct contact with the gate.

7. The semiconductor IC device of claim 1, wherein the bottom isolation region is composed of a first dielectric material and the bottommost inner spacer is composed of a second dielectric material different from the first dielectric material.

8. The semiconductor IC device of claim 1, wherein an interface between the S/D region and the backside contact is vertically inset within the bottom isolation region.

9. The semiconductor IC device of claim 1, wherein an interface between the S/D region and the backside contact is above the bottom isolation region.

10. A semiconductor integrated circuit (IC) device comprising:
a first region of the semiconductor IC device comprising a first gate, a first plurality of channels, a first source/drain (S/D) region; a first backside contact in direct contact with a backside of the first S/D region; a first bottom isolation region in direct contact with the first backside contact and in direct contact with the first gate;
a second region of the semiconductor IC device comprising a second gate, a second plurality of channels, a second S/D region; a second backside contact in direct contact with a backside of the second S/D region; a second bottom isolation region in direct contact with the second backside contact and in direct contact with the second gate; and
a shared backside interlayer dielectric (ILD) within the first region and within the second region, wherein the first gate directly connects the shared backside ILD, and wherein the second bottom isolation region separates the second gate from the shared backside ILD.

11. The semiconductor IC device of claim 10, wherein the first backside contact is asymmetric to the first S/D region and wherein the second backside contact is asymmetric to the second S/D region.

12. The semiconductor IC device of claim 10, wherein the first region of the semiconductor IC device further comprises a first bottommost inner spacer between the first bottom isolation region and a first bottommost channel of the first plurality of channels and wherein the second region of the semiconductor IC device further comprises a second bottommost inner spacer between the second bottom isolation region and a second bottommost channel of the second plurality of channels.

13. The semiconductor IC device of claim 10, wherein a sidewall of the first backside contact is horizontally inset within and below the first bottom isolation region.

14. The semiconductor IC device of claim 10, wherein a horizontal dimension of the first bottom isolation region is smaller than a horizontal dimension of the second bottom isolation region.

15. The semiconductor IC device of claim 10, wherein a bottom portion of the first gate has a smaller horizontal dimension relative to a top portion of the first gate and wherein a bottom portion of the second gate has a substantially same horizontal dimension relative to a top portion of the second gate.

16. The semiconductor IC device of claim 12, wherein the first bottom isolation region is composed of a first dielectric material and the first bottommost inner spacer is composed of a second dielectric material different from the first dielectric material.

17. The semiconductor IC device of claim 16, wherein the shared backside ILD is composed of a third dielectric material different from the first dielectric material and different from the second dielectric material.

18. The semiconductor IC device of claim 10, wherein a backside of the first gate is below a backside of the second gate.

19. The semiconductor IC device of claim 10, wherein respective horizontal dimensions of the first plurality of channels are larger than respective horizontal dimensions of the second plurality of channels.

20. A semiconductor integrated circuit (IC) device fabrication method comprising:
forming a first lateral indent within a lower sacrificial layer within a nanolayer stack while retaining a portion of the lower sacrificial layer;
forming a bottom isolation region within the first lateral indent directly against an upper sacrificial layer that is directly connected to a frontside of the lower sacrificial layer;
after forming the bottom isolation region, forming a second lateral indent within the upper sacrificial layer;
forming a bottom inner spacer within the second lateral indent directly against the bottom isolation region;
forming a gate directly against the bottom inner spacer and directly against the bottom isolation region; and
forming a backside contact direct against the bottom isolation region, wherein the bottom isolation region is between the backside contact and the gate.
